(19) United States
(12) Patent Application Publication
(10) Pub. No.: US 2005/0145953 A1
(43) Pub. Date: Jul. 7, 2005

(54) Heterojunction BiCMOS integrated circuits and method therefor

(75) Inventors: Lap Chan, Singapore (SG); Jia Zhen Zheng, Singapore (SG); Purakh Raj Verma, Singapore (SG); Jian Xun Li, Singapore (SG); Shao-fu Sanford Chu, Singapore (SG)

Correspondence Address: THE LAW OFFICES OF MIKIO ISHIMARU, 1110 SUNNYVALE-SARATOGA ROAD, SUITE A1, SUNNYVALE, CA, 94087, US

(73) Assignee: CHARTERED SEMICONDUCTOR MANUFACTURING LTD, Singapore (SG)

(21) Appl. No.: 10/752,454

(22) Filed: Jan. 5, 2004

(51) Int. Cl. H01L 21/331; H01L 31/113

(52) U.S. Cl. 257/378; 438/234; 438/309; 257/517; 438/205; 257/525

(57) ABSTRACT

A method of manufacturing a BiCMOS integrated circuit including a CMOS transistor having a gate structure, and a heterojunction bipolar transistor having an extrinsic base structure. A substrate is provided, and a polysilicon layer is formed over the substrate. The gate structure and the extrinsic base structure are formed in the polysilicon layer. A plurality of contacts is formed through the interlevel dielectric layer to the CMOS transistor and the heterojunction bipolar transistor.

### TECHNICAL FIELD

The present invention relates generally to semiconductor technology, and more particularly to a method and apparatus for manufacturing BiCMOS integrated circuits having a heterojunction bipolar transistor.

### BACKGROUND ART

Transistors are multi-electrode semiconductor devices in which the current flowing between two specified electrodes is controlled or modulated by the voltage applied at a third (control) electrode. Transistors fall into two major classes: field-effect transistors (FETs), and bipolar junction transistors (BJTs).

FETs include a source, a drain, and a gate. A voltage applied to the gate results in a current flow between the source and the drain of the FET through a channel that is formed beneath the gate. A commonly used FET is a complimentary metal oxide semiconductor (CMOS) transistor. CMOS transistors can be either NMOS or PMOS transistors depending upon the type of semiconductive materials used to form the transistor. NMOS transistors have n-type channels under their gates, and rely on electrons as charge carriers for electrical current. PMOS transistors have p-type channels under their gates, and rely on holes as charge carriers for electrical current. CMOS integrated circuit devices include both NMOS and PMOS transistors in one integrated circuit device.

BJTs comprise two p-n junctions placed back-to-back, with one of the regions common to both junctions. This forms either a p-n-p or an n-p-n transistor depending upon the characteristics of the semiconductive materials used. BJTs rely on both electrons and holes as charge carriers for electrical current.

A BJT is a three-terminal device that can controllably vary the magnitude of the electrical current that flows between two of the terminals. The three terminals include a base terminal, a collector terminal, and an emitter terminal. The movement of electrical charge carriers that produce electrical current flow between the collector and the emitter terminals varies dependent upon variations in the voltage on the base terminal thereby causing the magnitude of the current to vary. Thus, the electrical current flow through the emitter and collector electrodes is controlled by the voltage across the base-emitter junction.

Recently, demand for BJTs has increased significantly because these transistors are capable of operating at higher speeds and driving more current. These characteristics are important for high-speed, high-frequency communication networks such as those required by cell phones and computers.

BiCMOS integrated circuits devices include BJTs and CMOS transistors manufactured in the same integrated circuit device.

Heterojunction bipolar transistors (HBTs) are BJTs where the emitter-base junction is a heterojunction between semiconductor materials of different but similarly functioning types. Silicon/Silicon-Germanium (Si/SiGe) and Silicon/Silicon-Germanium-Carbon (Si/SiGeC) are two types of HBTs using compound semiconductive materials that have gained popularity due to their high-speed and low electrical noise capabilities, coupled with the ability to manufacture them using processing capabilities used in the manufacture of silicon BJTs. HBTs have found use in higher frequency applications such as cell phones, optical fiber, and other high-frequency applications requiring faster switching transistors, such as are used in satellite communication devices.

Although the use of compound semiconductive materials has proven useful in HBTs, problems exist in the manufacturing of HBTs. Once formed by existing methods, the compound semiconductive materials are subjected to multiple thermal cycles, implantations, and/or etching processes during subsequent formation steps of the remaining elements of the HBT such as the deposition and etching of oxide layers, nitride layers, and the emitter. Several of these processing steps inherently damage the compound semiconductive layer. Etching polysilicon, for example, adversely affects the compound semiconductive layer beneath the polysilicon because the etchants used do not selectively etch only the polysilicon. Some of the compound semiconductive layer is also etched during this processing step resulting in HBTs that are relatively slower and exhibit relatively poor electrical noise performance.

Furthermore, to improve the operating speed of a HBT, it is important that the base layer be thin enough to minimize the time it takes electronic charges to move from the emitter to the collector, thereby minimizing the response time of the transistor, and have a high concentration of dopant in order to minimize base resistance.

Typically, ion implantation techniques are widely used to form a base layer. However, this technique has the problem of ion channeling, which limits the minimum thickness of the base layer. Another disadvantage of ion implantation is that the Si/SiGe or Si/SiGeC layer is often damaged by the ions during implantation. Additionally, high-temperature annealing is required to drive the dopant into the material layers. This annealing step, however, alters the concentration profile within the various layers of semiconductive materials that make up the transistor.

Furthermore, the differences in manufacturing techniques used to form CMOS transistors and HBTs have made it difficult to manufacture BiCMOS integrated circuit devices using compound semiconductive materials that have proven to be beneficial in HBTs.

Solutions to these problems have been long sought but prior developments have not taught or suggested any solutions and, thus, solutions to these problems have long eluded those skilled in the art.

### DISCLOSURE OF THE INVENTION

The present invention provides a BiCMOS integrated circuit including a CMOS transistor having a gate structure, and a heterojunction bipolar transistor having an extrinsic base structure, and a method of manufacturing therefor. A substrate is provided, and a polysilicon layer is formed over the substrate. The gate structure and the extrinsic base structure are formed in the polysilicon layer. A plurality of contacts is formed through the interlevel dielectric layer to the CMOS transistor and the heterojunction bipolar transistor.

The present invention overcomes the problems associated with manufacturing BiCMOS integrated circuits including HBTs, and is readily suited for BiCMOS manufacturing processes.

Certain embodiments of the invention have other advantages in addition to or in place of those mentioned above. The advantages will become apparent to those skilled in the art from a reading of the following detailed description when taken with reference to the accompanying drawings.

### BRIEF DESCRIPTION OF THE DRAWINGS

FIG. 1 is a partial cross-sectional view of a portion of a BiCMOS integrated circuit including a heterojunction bipolar transistor (HBT) in an intermediate stage of manufacture in accordance with the present invention;

FIG. 2 is the structure of FIG. 1 after forming an NMOS transistor and a PMOS transistor;

FIG. 3 is an enlarged cross-sectional view of the HBT shown in FIGS. 1 and 2 in an intermediate stage of manufacture in accordance with the present invention;

FIG. 4 is the structure of FIG. 3 after formation of an intrinsic base structure in the HBT;

FIG. 5 is the structure of FIG. 4 after formation of an emitter structure in the HBT;

FIG. 6 is the structure of FIG. 2 after formation of the HBT, and a number of contacts through an interlevel dielectric layer; and

FIG. 7 is a flow chart of a method for manufacturing a BiCMOS integrated circuit device in accordance with the present invention.

### BEST MODE FOR CARRYING OUT THE INVENTION

In the following description, numerous specific details are given to provide a thorough understanding of the invention. However, it will be apparent to one skilled in the art that the invention may be practiced without these specific details. In order to avoid obscuring the present invention, some well-known configurations and process steps are not disclosed in detail.

Likewise, the drawings showing embodiments of the apparatus are semi-diagrammatic and not to scale and, particularly, some of the dimensions are for the clarity of presentation and are shown greatly exaggerated in the FIGs. Generally, the device can be operated in any orientation.

The term “horizontal” as used herein is defined as a plane parallel to the conventional plane or surface of a semiconductor wafer or substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “over”, and “under”, are defined with respect to the horizontal plane.

The term “processing” or “processed” as used herein includes deposition of material or photoresist, patterning, exposure, development, etching, cleaning, and/or removal of the material or photoresist as required in forming a described structure.

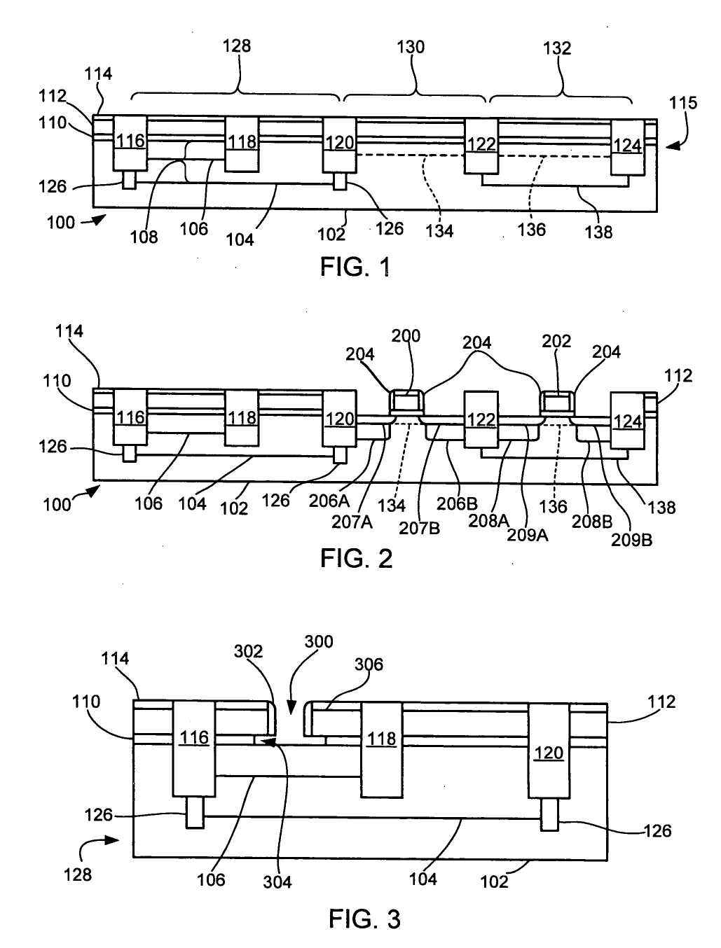

Referring now to FIG. 1, therein is shown a cross-sectional view of a portion of a bipolar complimentary metal oxide semiconductor (BiCMOS) integrated circuit 100 in an intermediate stage of manufacture in accordance with the present invention. The BiCMOS integrated circuit 100 includes a substrate 102, such as a lightly doped substrate of a first conductivity type, for example, a p⁻ doped silicon substrate. The substrate 102 has a buried collector region 104, such as a heavily doped region of a second conductivity type, for example, an n⁺ doped region. The substrate 102 also has a sub-collector region 106, such as a heavily doped region of the second conductivity type, for example, an n⁻ doped region. The buried collector region 104 and the sub-collector region 106 will be referred to herein collectively as a collector region 108.

The substrate 102 has a first insulating layer 110, such as an oxide layer. A polysilicon layer 112, such as a heavily doped polysilicon layer of the first conductivity type, for example, a p⁺ doped polysilicon layer, is formed over the first insulating layer 110. A second insulating layer 114, such as a nitride layer, is formed over the polysilicon layer 112, and can be used as a CMP stop layer. The second insulating layer 114 can be replaced with a substitute layer, such as an oxide layer, after performing the CMP to make the salicide process easier.

After formation of the first insulating layer 110, the polysilicon layer 112, and the second insulating layer 114, a number of shallow trench isolations (STIs) 115 are formed in the BiCMOS integrated circuit 100. The number of STIs 115 includes a first STI 116, a second STI 118, a third STI 120, a fourth STI 122, and a fifth STI 124. The first STI 116 and the third STI 120 also have beneath them a number of deep trench isolations (DTIs) 126.

The number of STIs 115 and the number of DTIs 126 are formed, for example, by etching a number of trenches through the second insulating layer 114, the polysilicon layer 112, and the first insulating layer 110, and extending into the substrate 102. The trenches are filled with an insulating material to form the number of STIs 115 and the number of DTIs 126. The surface is then processed using a chemical mechanical polish (CMP) process which stops on the second insulating layer 114 so that the upper surfaces of the number of STIs 115 are substantially coplanar with the upper surface of the second insulating layer 114.

For purposes of this description, the area between the first STI 116 and the third STI 120 will be referred to as a HBT 128. The area between the third STI 120 and the fourth STI 122 will be referred to as an NMOS transistor 130. The area between the fourth STI 122 and the fifth STI 124 will be referred to as a PMOS transistor 132.

The NMOS transistor 130 has a first channel region 134, such as a lightly doped region of the first conductivity type, for example, a p⁻ doped region, in the substrate 102. The PMOS transistor 132 has a second channel region 136, such as a lightly doped region of the second conductivity type, for example, an n⁻ doped region, in a well 138, such as a heavily doped region of the second conductivity type, for example, an n⁺ well.

The buried collector region 104 and the well 138 preferably are formed in the same processing step by processing the substrate 102 to implant the appropriate dopant in the selected regions of the substrate 102. Similarly, the sub-collector region 106 and the second channel region 136 preferably are formed in one processing step.

Referring now to FIG. 2, therein is shown the structure of FIG. 1 after forming the NMOS transistor 130 and the PMOS transistor 132.

An NMOS gate 200 of the NMOS transistor 130 is formed using readily available photolithographic processes well known in the semiconductor industry to mask the area of the NMOS gate 200. The portion of the second insulating layer 114 and the polysilicon layer 112 on either side of the NMOS gate 200 are etched to stop on the first insulating layer 110 thereby forming the NMOS gate 200. A PMOS gate 202 of the PMOS transistor 132 similarly is formed by masking and etching the selected area of the PMOS transistor 132 to stop on the first insulating layer 110.

After formation of the NMOS gate 200 and the PMOS gate 202, a number of insulating spacers 204, such as oxide spacers, nitride spacers, or combinations of both, are formed around the NMOS gate 200 and the PMOS gate 202.

The substrate 102 is then implanted to form a number of source/drain regions for the NMOS transistor 130 and the PMOS transistor 132 after removing the first insulating layer 110 over the areas for the source/drain regions.

In the NMOS transistor 130, for example, the NMOS gate 200 is implanted with a dopant to provide a first NMOS source/drain region 206A and a second NMOS source/drain region 206B. The first NMOS source/drain region 206A and the second NMOS source drain region 206B are heavily doped source/drain regions of the second conductivity type, for example, n⁺ source/drain regions. The NMOS transistor also has a first NMOS lightly doped drain (LDD) 207A and a second NMOS LDD 207B. The first NMOS LDD 207A and the second NMOS LDD 207B are formed by implanting a dopant to provide a lightly doped region of the second conductivity type, such as an n⁻ doped region.

Similarly, in the PMOS transistor 132, the area surrounding the PMOS gate 202 is implanted with a dopant to provide a first PMOS source/drain region 208A and a second PMOS source/drain region 208B. The first PMOS source/drain region 208A and the second PMOS source/drain region 208B are heavily doped source/drain regions of the first conductivity type, for example a p+ source/drain regions. The PMOS transistor also has a first PMOS LDD 209A and a second PMOS LDD 209B. The first PMOS LDD 209A and the second PMOS LDD 209B are formed by implanting a dopant to provide a lightly doped region of the first conductivity type, such as a p⁻ doped region.

Referring now to FIG. 3, therein is shown an enlarged cross-sectional view of the HBT shown in FIGS. 1 and 2 in an intermediate stage of manufacture in accordance with the present invention. The HBT 128 has an emitter window 300 formed in the first insulating layer 110, the polysilicon layer 112, and the second insulating layer 114. The emitter window 300 is formed by masking a portion of the area between the first STI 116 and the second STI 118 and performing suitable etching processes to form the emitter window 300.

Formation of the emitter window 300 creates an extrinsic base structure 306 that surrounds the emitter window 300. An insulating spacer 302 is formed in the emitter window 300. The insulating spacer 302 can comprise a single insulating material, such as nitride, or it can also be a multi-layered material, such as an oxide layer and a nitride layer.

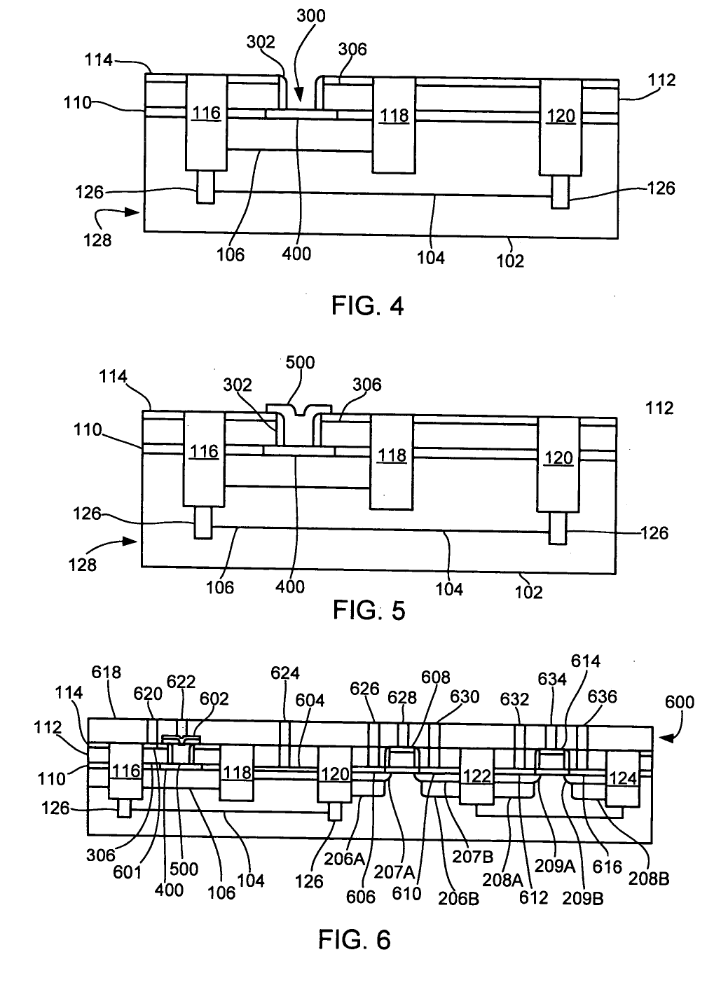

After formation of the insulating spacer 302 in the emitter window 300, an intrinsic base cavity 304 is formed in the first insulating layer 110. The first insulating layer 110 is etched using an isotropic etching process, such as a wet etch. The isotropic etching process results in an undercut area in the first insulating layer 110 to form the intrinsic base cavity 304. The intrinsic base cavity 304 extends beneath the insulating spacer 302 and partially under the extrinsic base structure 306 to ensure subsequent contact between the extrinsic base structure 306 and the intrinsic base structure 400 shown in FIG. 4 as discussed below.

Referring now to FIG. 4, therein is shown the structure of FIG. 3 after formation of an intrinsic base structure 400 in the HBT 128. The intrinsic base structure 400 is formed in the intrinsic base cavity 304 as an ultra thin structure. Preferably, the intrinsic base structure 400 comprises a semiconductor material selected from at least one of silicon, silicon-germanium (Si/Ge), silicon-germanium-carbon (Si/Ge/C), and combinations thereof. The intrinsic base structure 400 is formed in the intrinsic base cavity 304 by a selective formation process, such as by selective epitaxial growth.

The intrinsic base structure 400 preferably is doped during the selective formation process to form the intrinsic base structure 400 of the first conductivity type, such as a lightly doped semiconductor material, for example, a p⁻ doped semiconductor material. Doping of the intrinsic base structure 400 during its formation avoids the need for implantation of the dopant after formation of the intrinsic base structure 400.

Referring now to FIG. 5, therein is shown the structure of FIG. 4 after formation of an emitter structure 500 in the HBT 128. The emitter structure 500 is formed in the emitter window 300 shown in FIG. 4 by forming a semiconductive layer of material, such as by depositing a doped polysilicon material, such as a heavily doped polysilicon material of the second conductivity type, for example, an n⁺ doped polysilicon. The semiconductive layer is then processed to form the emitter structure 500 in the emitter window 300 over the intrinsic base structure 400.

Referring now to FIG. 6, therein is shown the structure of FIG. 2 after formation of the HBT 128 shown in FIG. 5, and a number of contacts 600 through an interlevel dielectric (ILD) layer 618. The various contact areas optionally can be provided with silicide layers, such as titanium silicide (TiSi₂), cobalt silicide (CoSi₂), or nickel silicide (NiSi) layers, to reduce contact resistance. For example, a base silicide layer 601 is provided over the extrinsic base structure 306, an emitter silicide layer 602 is provided over the emitter structure 500, and a collector silicide layer 604 is provided over the buried collector region 104 between the second STI 118 and the third STI 120.

Similarly, a first NMOS source/drain silicide layer 606 is provided over the first NMOS source/drain region 206A of the NMOS transistor 130. A NMOS gate silicide layer 608 is provided over the NMOS gate 200 of the NMOS transistor 130. A second NMOS source/drain silicide layer 610 is provided over the second NMOS source/drain region 206B of the NMOS transistor 130.

Similarly, a first PMOS source/drain silicide layer 612 is provided over the first PMOS source/drain region 208A of the PMOS transistor 132. A PMOS gate silicide layer 614 is provided over the PMOS gate 202 of the PMOS transistor 132. A second PMOS source/drain silicide layer 616 is provided over the second PMOS source/drain region 208B of the PMOS transistor 132.

After formation of the optional silicide layers, the ILD layer 618 is formed over the structures on the substrate 102, for example, by depositing an insulating material, such as oxide, and then performing a CMP process to planarize the upper surface of the ILD layer 618. The ILD layer 618 is then processed to form trenches that are filled with a conductive material, such as tungsten (W), to provide the number of contacts.

A base contact 620 is formed through the ILD layer 618 in contact with the base silicide layer 601 over the extrinsic base structure 306. An emitter contact 622 is formed through the ILD layer 618 in contact with the emitter silicide layer 602 over the emitter structure 500. A collector contact 624 is formed over the collector silicide layer 604 in contact with the buried collector region 104.

A first NMOS source/drain contact 626 is formed over the first NMOS source/drain region 206A of the NMOS transistor 130 in contact with the first NMOS source/drain silicide layer 606. An NMOS gate contact 628 is formed through the ILD layer 618 in contact with the NMOS gate silicide layer 608 over the NMOS gate 200. A second NMOS source/drain contact 630 is formed through the ILD layer 618 in contact with the second NMOS source/drain silicide layer 610 over the second source/drain region 206B of the NMOS transistor 130.

A first PMOS source/drain contact 632 is formed through the ILD layer 618 in contact with the first PMOS source/drain silicide layer 612 over the first PMOS source/drain region 208A. A PMOS gate contact 634 is formed through the ILD layer 618 in contact with the PMOS gate silicide layer 614 over the PMOS gate 202. A second PMOS source/drain contact 636 is formed through the ILD layer 618 in contact with the second PMOS source/drain silicide layer 616 over the second PMOS source/drain region 208B.

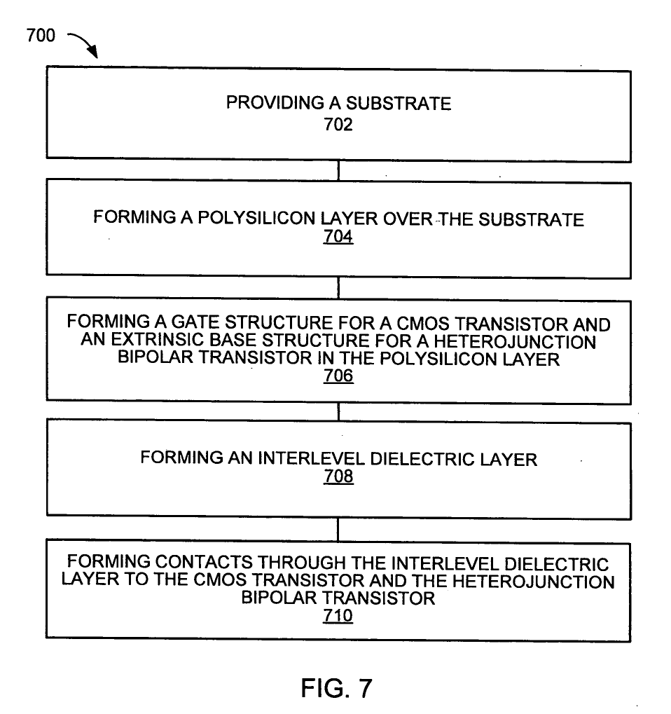

Referring now to FIG. 7, therein is shown a flow chart of a method 700 for manufacturing a BiCMOS integrated circuit including a CMOS transistor having a gate structure and a heterojunction bipolar transistor having an extrinsic base structure in accordance with the present invention. The method 700 includes a step 702 of providing a substrate; a step 704 of forming a polysilicon layer over the substrate; a step 706 of forming the gate structure and the extrinsic base structure in the polysilicon layer; a step 708 of forming an intrinsic base structure extending partially under the extrinsic base structure; a step 710 of forming an interlevel dielectric layer; and a step 712 of forming contacts through the interlevel dielectric layer to the CMOS transistor and the heterojunction bipolar transistor.

Thus, it has been discovered that the method and apparatus of the present invention furnish important and heretofore unavailable solutions, capabilities, and functional advantages for manufacturing BiCMOS integrated circuits having HBTs. The resulting process and configurations are straightforward, economical, uncomplicated, highly versatile, and effective, use conventional technologies, and are thus readily suited for manufacturing BiCMOS integrated circuits having HBTs that are fully compatible with conventional manufacturing processes and technologies.

While the invention has been described in conjunction with a specific best mode, it is to be understood that many alternatives, modifications, and variations will be apparent to those skilled in the art in light of the foregoing description. Accordingly, it is intended to embrace all such alternatives, modifications, and variations that fall within the spirit and scope of the included claims. All matters hither-to-fore set forth herein or shown in the accompanying drawings are to be interpreted in an illustrative and non-limiting sense.

1. A method of manufacturing a BiCMOS integrated circuit comprising:
providing a substrate;
forming a polysilicon layer over the substrate;
forming a gate structure for a CMOS transistor and an extrinsic base structure for a heterojunction bipolar transistor in the polysilicon layer;
forming an interlevel dielectric layer; and
forming a plurality of contacts through the interlevel dielectric layer to the CMOS transistor and the heterojunction bipolar transistor.

2. The method of manufacturing a BiCMOS integrated circuit as claimed in claim 1, further comprising:
forming an n-well for a CMOS transistor and a buried collector region for the heterojunction bipolar transistor in a first processing step; and
forming an n-channel for the CMOS transistor and a sub-collector region for the heterojunction bipolar transistor in a second processing step.

3. The method of manufacturing a BiCMOS integrated circuit as claimed in claim 1, further comprising forming an intrinsic base structure of a compound semiconductive material in the heterojunction bipolar transistor.

4. The method of manufacturing a BiCMOS integrated circuit as claimed in claim 3, wherein forming the intrinsic base structure further comprises,
forming an intrinsic base cavity under the polysilicon layer; and
forming the intrinsic base structure in the intrinsic base cavity.

5. The method of manufacturing a BiCMOS integrated circuit as claimed in claim 3, wherein forming the intrinsic base structure comprises forming an intrinsic base structure of at least one of silicon, silicon-germanium, silicon-germanium-carbon, and combinations thereof.

6. A method of manufacturing a BiCMOS integrated circuit including a CMOS transistor having a gate structure and a heterojunction bipolar transistor having an extrinsic base structure, comprising:
providing a lightly doped substrate of a first conductivity type;
forming a heavily doped polysilicon layer of the first conductivity type over the substrate;
forming a gate structure for a CMOS transistor and an extrinsic base structure for a heterojunction bipolar transistor in the heavily doped polysilicon layer;
forming a lightly doped intrinsic base structure of the first conductivity type extending partially under the extrinsic base structure;
forming an interlevel dielectric layer; and
forming a plurality of contacts through the interlevel dielectric layer to the CMOS transistor and the heterojunction bipolar transistor.

7. The method of manufacturing a BiCMOS integrated circuit as claimed in claim 6, further comprising:
forming a well of the second conductivity type for a CMOS transistor and a buried collector region of the second conductivity type for the heterojunction bipolartransistor in a first processing step; and
forming a channel of the second conductivity type for an CMOS transistor and a sub-collector region of the second conductivity type for the heterojunction bipolar transistor in a second processing step.

8. The method of manufacturing a BiCMOS integrated circuit as claimed in claim 6, further comprising forming an intrinsic base structure of a compound semiconductive material of the first conductivity type in the heterojunction bipolar transistor.

9. The method of manufacturing a BiCMOS integrated circuit as claimed in claim 8, wherein forming the intrinsic base structure further comprises:
forming an intrinsic base cavity under the polysilicon layer; and
forming the intrinsic base structure in the intrinsic base cavity.

10. The method of manufacturing a BiCMOS integrated circuit as claimed in claim 8, wherein forming the intrinsic base structure comprises forming an intrinsic base structure of at least one of silicon, silicon-germanium, silicon-germanium-carbon, and combinations thereof.

11. A BiCMOS integrated circuit comprising:
a substrate;
a polysilicon layer over the substrate;
a gate structure for a CMOS transistor and an extrinsic base structure for a heterojunction bipolar transistor in the polysilicon layer;
an interlevel dielectric layer; and
a plurality of contacts through the interlevel dielectric layer to the CMOS transistor and the heterojunction bipolar transistor.

12. The BiCMOS integrated circuit as claimed in claim 11, further comprising:
a CMOS transistor having an n-well and an n-channel; and
a buried collector region and a sub-collector region in the heterojunction bipolar transistor wherein the n-well and the buried collector region are the same conductivity type and the n-channel and the sub-collector region are the same conductivity type.

13. The BiCMOS integrated circuit as claimed in claim 11, further comprising an intrinsic base structure of a compound semiconductive material in the heterojunction bipolar transistor.

14. The BiCMOS integrated circuit as claimed in claim 13, wherein the intrinsic base structure further comprises:
an intrinsic base cavity under the polysilicon layer; and
the intrinsic base structure in the intrinsic base cavity.

15. The BiCMOS integrated circuit as claimed in claim 13, wherein the intrinsic base structure comprises at least one of silicon, silicon-germanium, silicon-germanium-carbon, and combinations thereof.

16. A BiCMOS integrated circuit comprising:
a lightly doped substrate of a first conductivity type;
a heavily doped polysilicon layer of the first conductivity type over the substrate;
a gate structure for a CMOS transistor and an extrinsic base structure for a heterojunction bipolar transistor in the heavily doped polysilicon layer;
a lightly doped intrinsic base structure of the first conductivity type extending partially under the extrinsic base structure;
an interlevel dielectric layer; and
a plurality of contacts through the interlevel dielectric layer to the CMOS transistor and the heterojunction bipolar transistor.

17. The BiCMOS integrated circuit as claimed in claim 16, further comprising:
a PMOS transistor having a well of a second conductivity type;
an NMOS transistor having a channel of the second conductivity type; and
a buried collector region of the second conductivity type and a sub-collector region of the second conductivity type in the heterojunction bipolar transistor wherein, the well for the PMOS transistor and the buried collector region for the heterojunction bipolar transistor are of the same conductivity type and the channel in the NMOS transistor and the sub-collector region in the heterojunction bipolar transistor are of the same conductivity type.

18. The BiCMOS integrated circuit as claimed in claim 16, further comprising an intrinsic base structure of a compound semiconductive material of the first conductivity type in the heterojunction bipolar transistor.

19. The BiCMOS integrated circuit as claimed in claim 18, wherein the intrinsic base structure further comprises:
an intrinsic base cavity under a portion of the polysilicon layer; and
the intrinsic base structure in the intrinsic base cavity.

20. The BiCMOS integrated circuit as claimed in claim 18, wherein the intrinsic base structure comprises an intrinsic base structure of at least one of silicon, silicon-germanium, silicon-germanium-carbon, and combinations thereof.
